(19) United States
(12) Patent Application Publication
(10) Pub. No.: US 2006/0209610 A1
(43) Pub. Date: Sep. 21, 2006

(54) Semiconductor memory and method for analyzing failure of semiconductor memory

(75) Inventor: Chiaki Dono, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY, INC.

(21) Appl. No.: 11/373,179

(22) Filed: Mar. 13, 2006

(30) Foreign Application Priority Data
Mar. 15, 2005 (JP) 2005-073823

(51) Int. Cl. G11C 7/00

(52) U.S. Cl. 365/222

(57) ABSTRACT

A counter controller stops a counter operation of a refresh counter to keep a counter output signal at a constant value when the counter output signal takes a predetermined value relating to a specific address. A state where the specific address is refreshed is maintained, and the failure analysis is carried out under the state.

### BACKGROUND OF THE INVENTION

This invention relates to a semiconductor memory and a method for analyzing a failure in a semiconductor memory, and more particularly to a semiconductor memory in which a refresh operation is carried out and to a method for analyzing a failure concerning a refresh operation for a specific address in a semiconductor memory.

A semiconductor memory, such as a dynamic random access memory (DRAM) and a pseudo static random access memory (PSRAM), simultaneously refreshes memory cells associated with a plurality of word lines. In the semiconductor memory, word lines activated in a refresh operation are more than that in an access operation. For example, known techniques of such refresh operation are disclosed in JP-A 2002-150770 and JP-A H09-180442, which are incorporated herein by reference in its entirety.

In general, if a failure occurs in a semiconductor memory, failure analysis is required to specify a mechanism of a source of the failure. For the failure analysis, there must be reproduced a situation where the failure occurs or another situation similar thereto.

As discussed previously, because the number of word lines activated in a refresh operation is greater than that of access operation, noise generated during the refresh operation is expected to be larger than that during the access operation. Therefore, if there is found out a failure concerning a refresh operation for a specific address, a specific situation must be reproduced where not an access operation for the specific address but the refresh operation for the specific address is carried out.

According to an existing technique, a plurality of refresh cycles are needed to repeatedly refresh the specific address because the refresh operation for the specific address is carried out only once in each refresh cycle. Thus, analysis of the failure concerning the specific situation needs a long time.

Therefore, it is an object of the present invention to provide a method for analyzing the failure concerning to the refresh operation which refreshes the specific address, wherein the refresh operation which refreshed the specific address is repeatedly reproduced in a short time. It is another object of the present invention to provide a semiconductor memory adapted to carry out the method.

### SUMMARY OF THE INVENTION

According to an aspect of the present invention, there is provided a method for analyzing a failure concerning a refresh operation for a specific address in a semiconductor memory and which comprises a refresh counter adapted to count how many times refresh operations are carried out and to generate a counter output signal and a decoder adapted to decode the counter output signal to simultaneously activate a set of word lines, wherein, when the counter output signal has a predetermined value, the decoder simultaneously activates a predetermined set of word lines relating to addresses including the specific address. The method comprises keeping the counter output signal at the predetermined value so as to maintain a state where the predetermined set of word lines are activated and analyzing a cause of the failure under the maintained state.

According to another aspect of the present invention, there is provided a semiconductor memory in which a refresh operation is carried out. The semiconductor memory comprises a refresh counter, a decoder and a counter controller. The refresh counter adapted to count how many times refresh operation is carried out and to generate a counter output signal. The decoder adapted to decode counter output signal to simultaneously activate a set of word lines. The counter controller adapted to control the refresh counter so that the refresh counter outputs a constant value of the counter output signal.

These and other objects, features and advantages of the present invention will become more apparent upon reading of the following detailed description along with the accompanied drawings.

### BRIEF DESCRIPTION OF THE DRAWINGS

FIG. 1 is a partial block diagram showing a semiconductor memory of an embodiment of the present invention, wherein some components are not shown for the sake of clarity;

FIG. 2 is a block diagram showing the counter controller and the refresh counter of FIG. 1; and

FIG. 3 is a timing chart showing variation of signals generated in the semiconductor memory of FIG. 1.

### DESCRIPTION OF PREFERRED EMBODIMENTS

A semiconductor memory according to an embodiment of the present invention is a synchronous dynamic random access memory (SDRAM) which comprises a mode resistor (not shown). The SDRAM according to this embodiment conforms to Joint Electron Device Engineering Council (JEDEC) standard. The SDRAM has a plurality of pins including A0-A13 pins. When the SDRAM receives a mode resister set (MRS) command, and the A7 pin (external pin) is in a high state and the A0-A6 pins and A8-A13 pins have predetermined values, the SDRAM is designed to be put into a predetermined test mode. The SDRAM is arranged to assert a test mode flag during the predetermined test mode. The asserted/negated test mode flag is used in a refresh counter control. The mode resistor and the test mode are shown, for example, in JP-A 2002-230996.

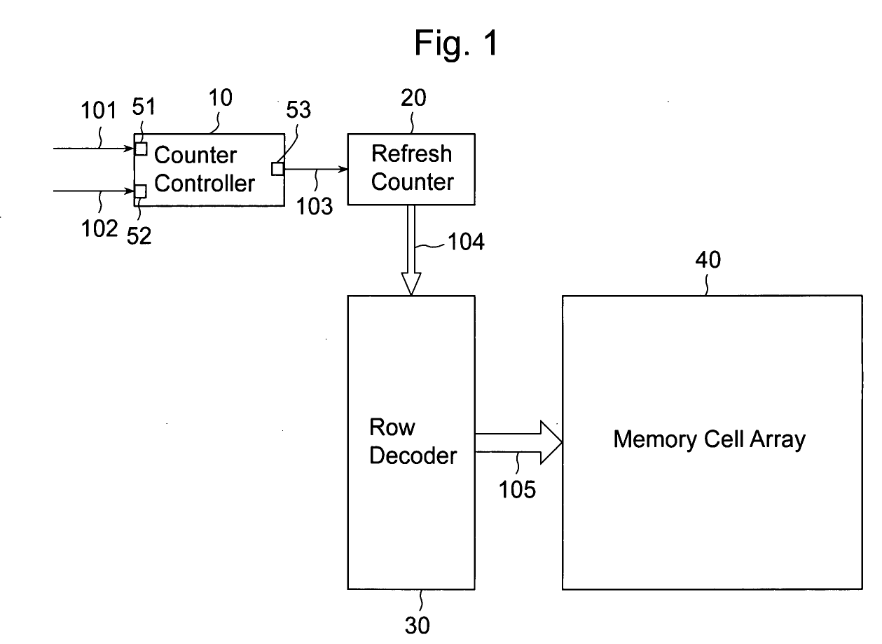

As shown in FIG. 1, the semiconductor memory comprises a counter controller 10, a refresh counter 20, a row decoder 30 and a memory cell array 40. Some components are not shown in FIG. 1 for the sake of clarity.

The counter controller 10 comprises a first input portion 51, a second input portion 52 and an output portion 53. The first input portion 51 is for receiving a refresh command signal 101 which is applied in a form of a pulse. The second input portion 52 is for receiving a test mode flag 102. The counter controller 10 generates a counter control signal 103 based on the refresh command signal 101 and the test mode flag 102 and outputs the counter control signal 103 through the output portion 53. A count of the pulses relates to the number of times refresh operations are carried out.

When the test mode flag 102 is negated, the counter controller 10 outputs the refresh command signal 101 as the counter control signal 103, which includes pulses relating to the count of refresh operations. When the test mode flag 102 is asserted, the counter controller 10 outputs a constant value as a counter control signal 103.

The refresh counter 20 comprises a structure similar to that of a known semiconductor memory and counts the pulses included in the counter control signal 103 to generate the counter output signal 104. The counter output signal 104 is also called an internal address.

The row decoder 30 comprises a structure similar to that of a known semiconductor memory. The row address decoder 30 decodes the counter output signal 104 to generate a plurality of row addresses 105, in accordance with which a plurality of word lines are activated so that a plurality of memory cells coupled to the activated word lines are refreshed.

To know row addresses activated by the row decoder 30, various known techniques can be applied.

For example, if the refresh counter 20 is provided with a reset function, the reset function can be used to know row addresses activated by the row decoder 30. In detail, because a relation between an internal address (i.e. counter output signal 104) and row addresses 105 to be activated is known, if an internal address can be specified, the row addresses 105 corresponding thereto also can be specified. On the other hand, a value of the counter output signal 104 after a reset operation can be understood from the number of refresh commands included in the refresh command signal 101 after the reset operation, provided that the test mode flag 102 is negated. Therefore, row addresses to be activated by the row decoder 30 can be known by counting the number of refresh commands included in the refresh command signal 101 after a reset operation for the refresh counter 20.

Even if the refresh counter 20 is not provided with a reset function, row addresses to be activated can be known by the following manner. When a first refresh command is issued so that a first set of row addresses is activated, a value of “0” is written into each of memory cells corresponding to the first set of row addresses. When a second refresh command issued so that a second set of row addresses is activated, another value of “1” is written into each of memory cells corresponding to the second set of row addresses. Subsequently, until the refresh counter completes one cycle, issue of refresh command is repeatedly carried out so that the value of “1” is written into each of memory cells relating to the refresh command, likewise. As apparent from these write operations, the value of “0” is written only in the memory cells corresponding to the first refresh command, i.e. the memory cells corresponding to the initial value of the refresh counter 20. Therefore, the first set of row addresses can be obtained, for example, by read operations to specify where the value of “0” is written. In addition, row addresses to be activated by the row decoder 30 can be known by counting the number of refresh commands included in the refresh command signal 101 and by assuming transition of row addresses from the first set of row adderesses.

As explained above, the counter controller 10 of the present embodiment can causes the refresh counter 20 to stop the count operation when the row address 105 includes a specific address that is a target of failure analysis. Then, the refresh counter 20 outputs a constant value as the counter output signal 104, which relates to the specific address.

Therefore, with repeatedly refreshing a word line relating to the specific address, the failure analysis can be carried out.

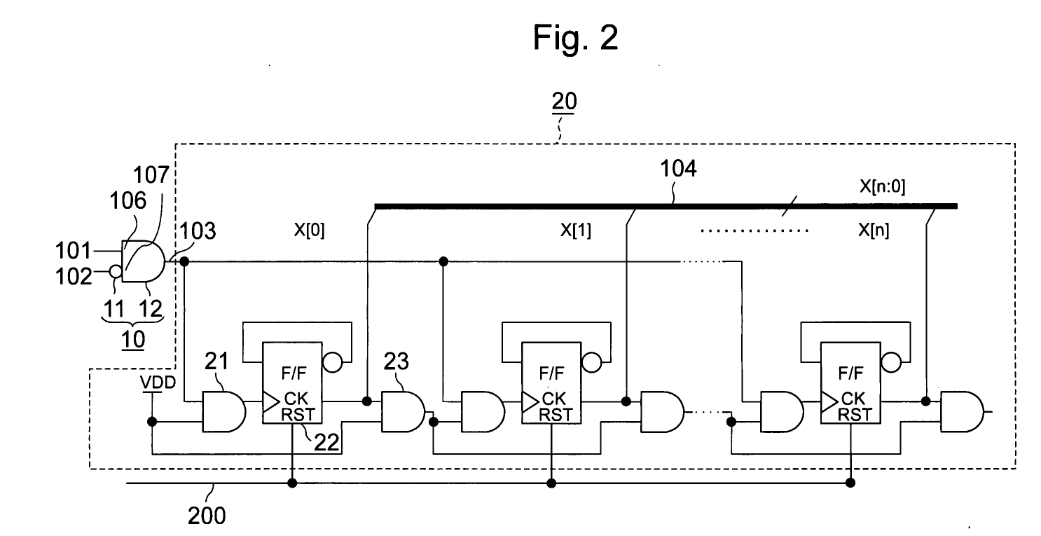

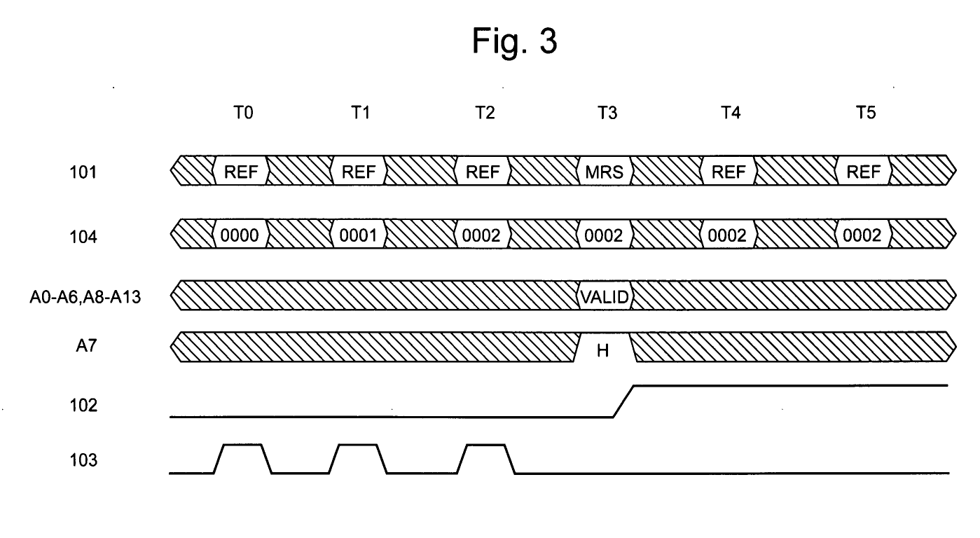

FIG. 2 shows, a detailed structure of the counter controller 10 and the refresh counter 20 of this embodiment. FIG. 3 is a timing chart showing variation of the counter output signal 104 and so on.

As shown in FIG. 2, the counter controller 10 of this embodiment comprises an inverter 11 and a two input AND gate 12. The AND gate 12 is provided with a first terminal 106 and a second terminal 107. The first terminal 106 is for receiving the refresh command signal 101. The second terminal 107 is for receiving the test mode flag 102 through an inverter 11.

From the explained structure, it can be clearly understood that, during the test mode flag 102 is in a low state “L”, the AND gate 12 outputs the counter control signal 103 corresponding to the refresh command signal 101. On the other hand, during the test mode flag 102 is in a high state “H”, the AND gate 12 keeps outputting the counter control signal 103 in a low state “L”.

The refresh counter 20 is provided with cascade connection of n (n is a natural number) sets of units each of which comprises an input AND gate 21, a flip-flop (F/F) 22 and an output AND gate 23. Each of the flip-flops 22 is provided with a reset terminal (RST). The reset terminal is connected to a power up signal line 200. When a power is supplied to the semiconductor memory, each of the flip-flops 22 is reset, and the counter output signal 104 takes default value “0”.

Regarding to FIG. 3, in the period from T0 to T2, refresh commands are issued three times (see the refresh command signal 101), while the test mode flag 102 is negated, so that the pulses are appeared on the counter control signal 103 in response to the number of the refresh commands. The counter output signal 104 is incremented in responsive to the counter control signal 103 and, especially, has a value “0002” at T2.

At T3, the MRS command is issued, the A7 pin is placed in “H” and the A0-A6 and A8-A13 pins have the predetermined values so that the SDRAM is put into the predetermined test mode, and the test mode flag 102 is asserted. The test mode flag 102 of this embodiment is a request signal to cause the refresh counter 20 to stop the count operation.

According to the asserted test mode flag 102, in the period after T4, the counter control signal 103 takes a constant value. Therefore, the refresh counter 20 stops the count operation and keeps outputting of the last value of the counter output signal 104, i.e. “0002”, while further refresh commands are issued (see the refresh command signal 101). Thus, a plurality of row addresses relating to “0002” is repeatedly refreshed.

The above mentioned embodiment, the SDRAM is described as a semiconductor memory as an example. However, a concept of the present invention is not limited to those mentioned above. A semiconductor memory may be one which determines an object of a refresh operation by using a refresh counter. The concept of the present invention can be applied to ones, for example to a PSRAM which is substantially consists of a DRAM.

This application is based on Japanese Patent Application serial no. 2005-073823 filed in Japan Patent Office on Mar. 15, 2005, the contents of which are hereby incorporated by reference.

Although the present invention has been fully described by way of example with reference to the accompanying drawings, it is to be understood that various changes and modifications will be apparent to those skilled in the art. Therefore, unless otherwise such changes and modifications depart from the scope of the present invention hereinafter defined, they should be constructed as being included therin.

What is claimed is:

1. A method for analyzing a failure concerning a refresh operation for a specific address in a semiconductor memory and which comprises a refresh counter adapted to count how many times refresh operations are carried out and to generate a counter output signal and a decoder adapted to decode the counter output signal to simultaneously activate a set of word lines, wherein, when the counter output signal has a predetermined value, the decoder simultaneously activates a predetermined set of word lines relating to addresses including the specific address, the method comprising:
keeping the counter output signal at the predetermined value so as to maintain a state where the predetermined set of word lines are activated; and
analyzing a cause of the failure under the maintained state.

2. A semiconductor memory in which a refresh operation is carried out and which comprises:
a refresh counter adapted to count how many times refresh operations are carried out and to generate a counter output signal;
a decoder adapted to decode counter output signal to simultaneously activate a set of word lines; and
a counter controller adapted to control the refresh counter so that the refresh counter outputs a constant value of the counter output signal.

3. The semiconductor memory according to claim 2, wherein:
the counter controller comprises a first input portion adapted to receive a refresh signal in a pulse form, a second input portion adapted to receive a request signal, and an output portion which outputs a counter control signal, wherein the counter controller outputs the refresh signal as the counter control signal when the request signal is inactive, while the counter controller outputs a constant value as the counter control signal when the request signal is active; and
the refresh counter counts pulses included in the counter control signal to generates the counter output signal.

4. The semiconductor memory according to claim 3, wherein:
the counter controller comprises a two input AND gate, wherein the two input AND gate includes a first terminal and a second terminal, and the first terminal is connected to the first input portion; and
the counter controller is arranged so that the second terminal is provided with a high level when the request signal is inactive and that the second terminal is provided with a low level when the request signal is active.

5. The semiconductor memory according to claim 2, wherein the semiconductor device is a DRAM.

6. The semiconductor memory according to claim 2, wherein the semiconductor device is a PSRAM.
